(19) United States
(12) Patent Application Publication
(10) Pub. No.: US 2024/0324170 A1
(43) Pub. Date: Sep. 26, 2024

(54) SEMICONDUCTOR DEVICE MANUFACTURING METHOD

(71) Applicant: Kioxia Corporation, Tokyo (JP)

(72) Inventors: Masaya TODA, Yokkaichi Mie (JP); Kazuhiro MATSUO, Kuwana Mie (JP); Ha HOANG, Kuwana Mie (JP); Kota TAKAHASHI, Latham, NY (US); Kenichiro TORATANI, Fujisawa Kanagawa (JP); Wakako MORIYAMA, Yokohama Kanagawa (JP)

(21) Appl. No.: 18/589,286

(22) Filed: Feb. 27, 2024

(30) Foreign Application Priority Data
Mar. 24, 2023 (JP) 2023-047815

(51) Int. Cl. H10B 12/00

(52) U.S. Cl. CPC H10B 12/05; H10B 12/33

(57) ABSTRACT

A semiconductor device manufacturing method includes transferring a substrate including a structure that has a first surface at which indium is exposed, and a second surface at which a metal is exposed, to a chamber of a film forming device, supplying an indium reducing gas to the chamber at a first temperature at which indium is able to transition to a gaseous state, and supplying a film forming gas to the chamber at a second temperature higher than the first temperature to form a first film on the first surface and the second surface, after supplying the reducing gas.

### CROSS-REFERENCE TO RELATED APPLICATION(S)

This application is based upon and claims the benefit of priority from Japanese Patent Application No. 2023-047815, filed Mar. 24, 2023, the entire contents of which are incorporated herein by reference.

### FIELD

Embodiments described herein relate generally to a semiconductor device manufacturing method.

### BACKGROUND

Among semiconductor devices, there are those on which a film including an indium oxide and a film including tungsten are formed. During a semiconductor device manufacturing process of the related art, a whisker may be formed when indium adheres to a film including a metal such as tungsten.

### DESCRIPTION OF THE DRAWINGS

FIG. 1 is a circuit diagram for illustrating an example of a circuit configuration of a memory cell array according to a first embodiment.

FIG. 2 is a sectional schematic view for illustrating an example of a structure of a semiconductor storage device according to the first embodiment.

FIGS. 3-7 are schematic views showing the semiconductor device manufacturing process according to the first embodiment.

FIGS. 8-10 are each a schematic view showing one example of a problem in a semiconductor device manufacturing process.

FIGS. 11-12 are schematic views for illustrating a reaction between different indium reducing gases and ITO in the semiconductor storage device according to the first embodiment.

FIG. 13 is a schematic view showing a semiconductor device manufacturing process according to a second embodiment.

FIG. 14 is a schematic view showing a semiconductor device manufacturing process according to a third embodiment.

FIG. 15 is a schematic view showing a semiconductor device manufacturing process according to a fourth embodiment.

FIG. 16 is a schematic view showing a semiconductor device manufacturing process according to a fifth embodiment.

### DETAILED DESCRIPTION

Embodiments provide a semiconductor device manufacturing method such that a formation of a whisker on a film including a metal can be suppressed.

In general, according to one embodiment, a semiconductor device manufacturing method includes transferring a substrate including a structure that has a first surface at which indium is exposed, and a second surface at which a metal is exposed, to a chamber of a film forming device, supplying an indium reducing gas to the chamber at a first temperature at which indium transitions to a gaseous state, and supplying a film forming gas to the chamber at a second temperature higher than the first temperature to form a first film on the first surface and the second surface, after supplying the reducing gas.

Hereafter, embodiments will be described while referring to the attached drawings. In order to facilitate understanding of the description, identical reference signs are assigned, as far as possible, to identical elements in the drawings, and redundant descriptions are omitted.

### First Embodiment

A configuration of a semiconductor storage device according to a first embodiment will be described. In each drawing, an X axis, a Y axis, and a Z axis may be shown. The X axis, the Y axis, and the Z axis form a right-handed three-dimensional coordinate system. Hereafter, an X axis arrow direction may be called an X axis+direction, and a direction opposite to that of the arrow an X axis-direction, with the same also applying to the other axes. The Z axis+direction and the Z axis-direction may also be called “upward” and “downward” respectively. Also, planes perpendicular to the X axis, the Y axis, or the Z axis may be called a YZ plane, a ZX plane, or an XY plane respectively. Also, a Z axis direction may be called an “up-down direction”. “Upward”, “downward”, and “up-down direction” are merely terms indicating a relative positional relationship in a drawing, and are not necessarily terms that establish an orientation having a vertical direction as a reference.

In the present specification, “connection” includes not only a physical connection but also an electrical connection, and includes not only a direct connection but also an indirect connection, unless particularly specified.

A semiconductor storage device 101 according to the first embodiment is an oxide semiconductor random-access memory (OS-RAM), and includes a memory cell array.

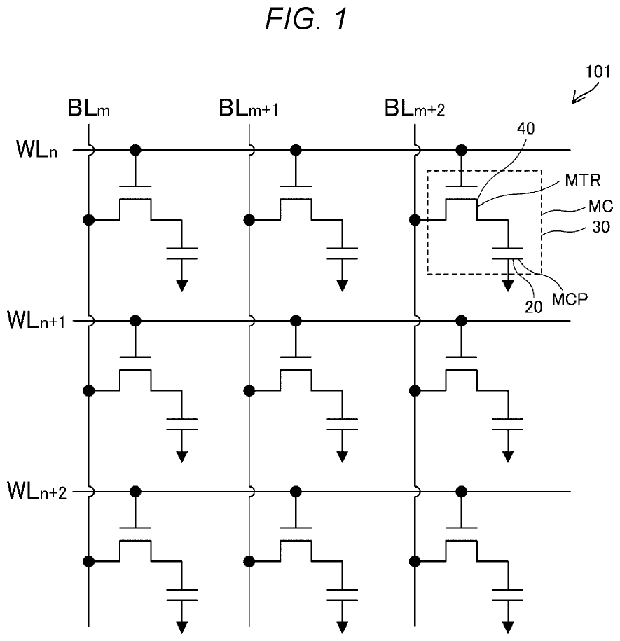

As shown in FIG. 1, the memory cell array includes a multiple of memory cells MC, a multiple of word lines WL, and a multiple of bit lines BL.

A word line WLₙ, a word line WLₙ₊₁, and a word line WLₙ₊₂ are shown as one example of multiple word lines WL in FIG. 1 (herein, n is a positive integer). Also, a bit line BLₘ, a bit line BLₘ₊₁, and a bit line BLₘ₊₂ are shown as one example of multiple bit lines BL in FIG. 1 (herein, m is a positive integer). The number of multiple memory cells MC is not limited to the number shown in FIG. 1.

The memory cell array is formed by multiple memory cells MC being arranged in, for example, a matrix form. The memory cell MC includes a memory transistor MTR, which is a field-effect transistor (FET), and a memory capacitor MCP.

A series of the memory cells MC provided in a row direction is connected to the word line WL (for example, the word line WLₙ) corresponding to the row to which the series of the memory cells MC belongs (for example, an n^{th} row). A series of the memory cells MC provided in a column direction is connected to the bit line BL (for example, the bit line BLₘ₊₂) corresponding to the column to which the series of the memory cells MC belongs (for example, an m+2 column).

Specifically, a gate of the memory transistor MTR in the memory cell MC is connected to the word line WL corresponding to the row to which the memory cell MC belongs. One of a source or a drain of the memory transistor MTR is connected to the bit line BL corresponding to the column to which the memory cell MC belongs.

One electrode of the memory capacitor MCP in the memory cell MC is connected to the other of the source or the drain of the memory transistor MTR in the memory cell MC. The other electrode of the memory cell MC is connected to a power supply line (not shown) that supplies a specific voltage.

The memory cell MC is configured in such a way as to be able to store data owing to an accumulation of a charge in the memory capacitor MCP caused by a current flowing through the corresponding bit line BL in accordance with a switching by the memory transistor MTR based on a voltage of the corresponding word line WL.

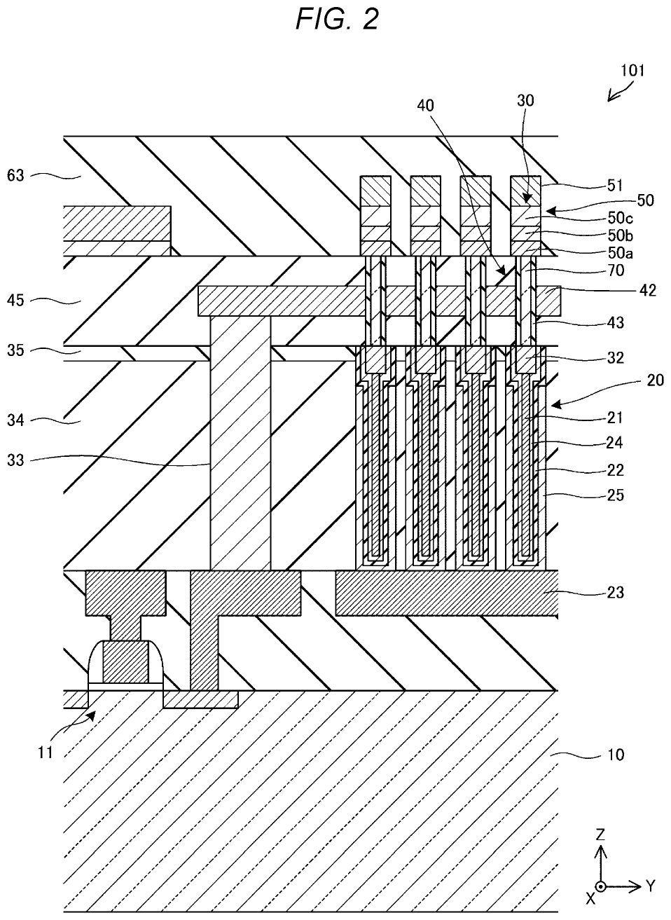

As shown in FIG. 2, the semiconductor storage device 101 includes a semiconductor substrate 10, a circuit 11, a capacitor 20, a semiconductor device 30, a conductor 33, and insulating layers 34, 35, 45, and 63.

The capacitor 20 includes a conductor 21, an insulating film 22 (one example of a “dielectric film”), a conductor 23, a capacitor electrode 24 (one example of a “first capacitor electrode”), and a capacitor electrode 25 (one example of a “second capacitor electrode”).

The semiconductor device 30 includes a field-effect transistor 40 (one example of a “semiconductor element”), an upper electrode 50 provided above the field-effect transistor 40, and a lower electrode 32 (one example of a “second conductive film”) provided below the field-effect transistor 40.

The field-effect transistor 40 includes an oxide semiconductor layer 70 (one example of a an “oxide semiconductor”) corresponding to a channel, a gate insulating film 43 (one example of a “film”), and a conductive layer 42 (one example of a “gate electrode”).

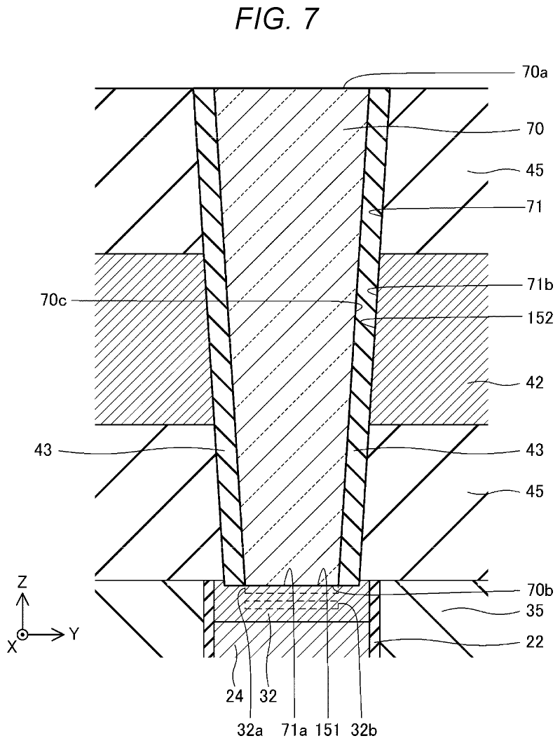

The oxide semiconductor layer 70 is formed in the insulating layer 45, and has an upper end 70a (one example of a “first end”) and a lower end 70b (one example of a “second end”). The oxide semiconductor layer 70 is a columnar body that extends in the Z axis+direction (one example of a “first direction”) from the lower end 70b toward the upper end 70a (see FIG. 7). The oxide semiconductor layer 70 forms a channel of the field-effect transistor 40, and the oxide semiconductor layer 70 has an amorphous structure.

The conductive layer 42 functions as a gate electrode of the field-effect transistor 40, and is opposed across the gate insulating film 43 between the upper end 70a and the lower end 70b of the oxide semiconductor layer 70. The conductive layer 42 corresponds to the word line WL (refer to FIG. 1), and extends along an axis of extension parallel to the Y axis.

The gate insulating film 43 is, for example, a silicon nitride film (Si₃N₄) including silicon and nitrogen.

The upper electrode 50 is formed in the Z axis+direction with respect to the oxide semiconductor layer 70. The upper electrode 50 includes a metal oxide layer 50a (one example of a “first conductive film”), a barrier metal layer 50b, and a metal film 50c.

The metal film 50c includes tungsten (W) (one example of a “first metal”). The metal oxide layer 50a is formed between the metal film 50c and the upper end 70a of the oxide semiconductor layer 70. The metal oxide layer 50a includes indium. The metal oxide layer 50a includes, for example, indium and oxygen. More generally, the metal oxide layer 50a includes, for example, a metal oxide. The metal oxide includes, for example, indium and tin as metal elements. In the present embodiment, the metal oxide layer 50a is formed of indium tin oxide (ITO).

The barrier metal layer 50b includes titanium and nitrogen, and is formed between the metal oxide layer 50a and the metal film 50c. In the present embodiment, the barrier metal layer 50b is formed of, for example, titanium nitride (TiN).

The conductive layer 51 is formed to come into contact with at least one portion of an upper face of the upper electrode 50. The conductive layer 51 corresponds to the bit line BL (refer to FIG. 1), and extends along an axis of extension parallel to the X axis.

The insulating layer 63 is formed above the insulating layer 45. The insulating layer 63 covers the upper electrode 50 and the conductive layer 51.

The lower electrode 32 comes into contact with the lower end 70b (one example of a “second end”) of the oxide semiconductor layer 70. The lower electrode 32 includes indium. The lower electrode 32 includes, for example, indium and oxygen. More generally, the lower electrode 32 includes, for example, a metal oxide. The lower electrode 32 is formed of, for example, an ITO layer including a metal oxide such as indium tin oxide, that is, ITO (one example of an “indium oxide”).

The circuit 11 forms a peripheral circuit of a decoder for selecting a predetermined memory cell MC of the multiple of memory cells MC, that is, the capacitor 20 and the field-effect transistor 40, of the semiconductor storage device 101, a sense amplifier connected to the bit line BL, a register configured with an SRAM, and the like. The circuit 11 may include a CMOS circuit having field-effect transistors that are a P-channel field-effect transistor (a Pch-FET) and an N-channel field-effect transistor (an Nch-FET) formed using a CMOS process.

A field-effect transistor of the circuit 11 can be formed using the semiconductor substrate 10, which is, for example, a single-crystal silicon substrate. The Pch-FET and the Nch-FET are so-called lateral field-effect transistors that have a channel region, a source region, and a drain region in the semiconductor substrate 10, and have a channel for causing a carrier to flow in the X or Y axis direction approximately parallel to a surface of the semiconductor substrate 10, in a region in proximity to the surface of the semiconductor substrate 10. The semiconductor substrate 10 may have a P-type or an N-type conductivity. For the sake of convenience, FIG. 2 shows one example of a field-effect transistor of the circuit 11.

The capacitor 20 is the memory capacitor MCP in the memory cell MC (refer to FIG. 1). Although four capacitors 20 are shown in FIG. 2, the number of capacitors 20 is not limited to four.

In the present embodiment, the capacitor 20 is provided above the semiconductor substrate 10. The capacitor electrode 24 of the capacitor 20 is connected to the conductor 21 and the lower electrode 32. The capacitor electrode 25 opposes the capacitor electrode 24. The insulating film 22 is provided between the capacitor electrode 24 and the capacitor electrode 25.

The capacitor 20 is a three-dimensional capacitor such as a pillar-type capacitor. A capacitor having a different configuration that allows for charges to be accumulated therein may also be employed as a capacitor of the present embodiment.

The conductor 21 comes into contact with a lower end face of the lower electrode 32, and has a form that extends downward from the end face. The capacitor electrode 24 is formed to cover the lower electrode 32 and the conductor 21. The insulating film 22 is formed to cover the capacitor electrode 24. The capacitor electrode 25 surrounds one lower portion of the insulating film 22, and has a lower end that comes into contact with an upper end face of the conductor 23.

The conductor 21 may include a material such as amorphous silicon. The insulating film 22 may include a material such as hafnium oxide. The conductor 23 and the capacitor electrodes 24 and 25 may include a material such as tungsten (W) or titanium nitride (TIN).

The conductor 33 includes wiring that electrically connects the circuit 11 and the semiconductor device 30. The conductor 33 has via wiring that extends in the Z axis direction and connects the word line WL and the circuit 11 provided on the semiconductor substrate 10, as shown in, for example, FIG. 2. The conductor 33 includes, for example, copper.

The insulating layer 34 is provided around capacitors 20. The insulating layer 34 is, for example, a silicon oxide film including silicon and oxygen.

The insulating layer 35 is provided above the insulating layer 34. The insulating layer 35 is, for example, a silicon nitride film including silicon and nitrogen.

The semiconductor device 30 is provided above the capacitor 20. The field-effect transistor 40 of the semiconductor device 30 corresponds to the memory transistor MTR of the memory cell MC (refer to FIG. 1).

In the semiconductor device 30, the field-effect transistor 40 is provided above the lower electrode 32. Specifically, the oxide semiconductor layer 70 of the field-effect transistor 40 is positioned in a direction away from the semiconductor substrate 10, that is, upward, with respect to the lower electrode 32.

The upper electrode 50 is positioned in a direction away from the semiconductor substrate 10, that is, upward, with respect to the oxide semiconductor layer 70. Because of this configuration, the field-effect transistor 40 is a so-called vertical transistor having a channel that extends in the Z axis direction (an up-down direction) approximately vertical to the surface of the semiconductor substrate 10.

Also, the oxide semiconductor layer 70 is a semiconductor in which an oxygen vacancy serves as a donor, and includes indium (In), zinc (Zn), and gallium (Ga) as metal elements. Specifically, the oxide semiconductor layer 70 is an oxide of indium, gallium, and zinc, that is, an IGZO (InGaZnO). Alternatively, the oxide semiconductor layer 70 may be another kind of oxide semiconductor.

Although a structure in which the semiconductor device 30 is provided above the capacitor 20 is shown, a structure in which the capacitor 20 is provided above the semiconductor device 30 may also be adopted.

### Semiconductor Device Manufacturing Method

Hereafter, a method of manufacturing the semiconductor device 30 will be described as one example of a semiconductor device manufacturing method according to the first embodiment.

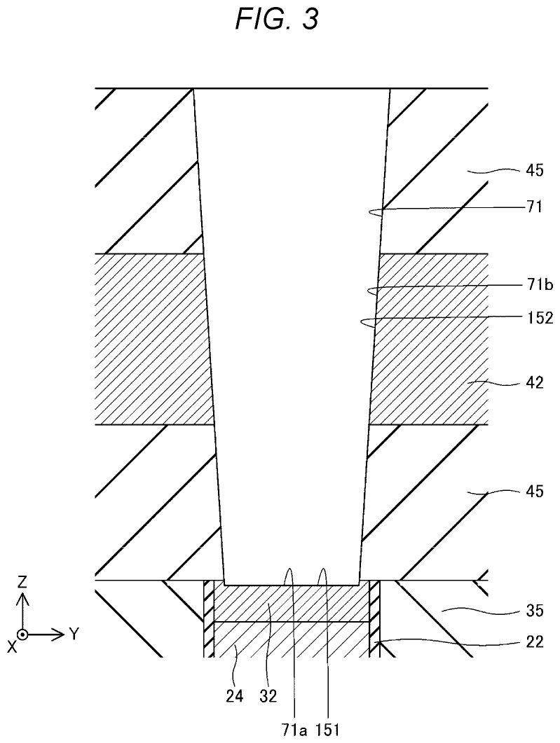

Firstly, as shown in FIG. 3, a hole portion 71 is formed to penetrate in the up-down direction by carrying out etching of the insulating layer 45 and the conductive layer 42 formed on a semiconductor substrate.

The hole portion 71 is, for example, a transistor hole. A lower portion of the hole portion 71 is a bottom face 71a. The bottom face 71a includes a surface 151 in which ITO is exposed. Specifically, the surface 151 is one portion of the lower electrode 32 exposed when the hole portion 71 is formed.

The X axis direction and the Y axis direction of the hole portion 71 form a side face 71b. The side face 71b includes a surface 152 in which tungsten is exposed. Specifically, the surface 152 is one portion of the conductive layer 42 exposed when the hole portion 71 is formed.

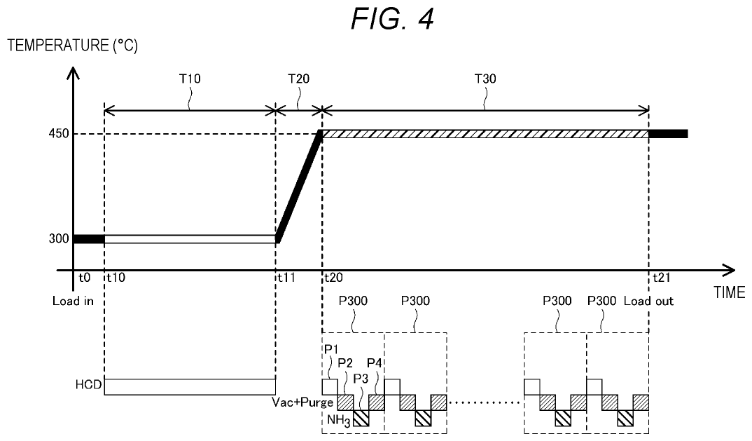

Next, the gate insulating film 43 is formed in the hole portion 71. The formation of the gate insulating film 43 is carried out as shown in FIG. 4. Firstly, a semiconductor substrate including the semiconductor device 30 is loaded into a film forming device at a time to (Load in). The film forming device forms a film using, for example, atomic layer deposition (ALD). The film forming device includes a chamber to which the semiconductor substrate is transferred. The chamber includes a holder in which the transferred semiconductor substrate is disposed. Furthermore, the semiconductor substrate can be heated using a heater provided in an interior of the holder.

Next, in a soaking period T10 from a time t10 to a time t11, a reducing gas supply process is carried out as a process preliminary to a process of forming the gate insulating film 43. During the reducing gas supply process, an indium reducing gas is supplied at a first temperature to the hole portion 71 including the surface 151 and the surface 152.

The first temperature is preferably 350 degrees Celsius or less. In the present embodiment, the first temperature is, for example, 300 degrees Celsius. This temperature is referred to herein as a heater setting temperature.

The indium reducing gas is, for example, a gas of an inorganic material or a gas of an organic material. The gas of the inorganic material includes, for example, an Si—X bond. Herein, X is a halogen such as F, Cl, Br, I, or At.

The gas of the inorganic material is, for example, a halide. The gas of the inorganic material is, for example, HSᵢCl₃ (trichlorosilane: TCS), H₂SiCl₂ (dichlorosilane: DCS), (SiCl₃)₂ (hexachlorodisilane: HCD), or SiH₂I₂ (diiodosilane).

The gas of the organic material includes at least one of, for example, a C—H bond and an N—C—H bond. Specifically, the gas of the organic material is, for example, a gas in which three amino groups are bonded with SiH, such as [(CH₃)₂N]₃SiH (Tris(dimethylamino)silane:TrisDMAS), a gas in which two amino groups are bonded with SiH₂, such as [NH(C₄H₉)]₂SiH₂ (Bis(tertiary-butylamino)silane: BTBAS), a mono-aminosilane series material, or a carbon material.

Also, the gas of the organic material may be a gas that does not include silicon. The gas of the organic material is, for example, a gas in which a metal such as Al, Ti, Zr, or Hf and a gas having an amino group or a C_{N}—H_{M} bond are bonded. The gas of the organic material is, for example, trimethylaluminum (TMA).

During the reducing gas supply process in the soaking period T10, a pressure in the chamber is 10 Pa to 2,000 Pa. The indium reducing gas is, for example, HCD. The HCD is supplied together with an N₂ gas into the chamber at 1 to 2,000 sccm (standard cc/min).

A length of the soaking period T10 is 1 to 30 minutes. In the present embodiment, the length of the soaking period T10 is, for example, 10 minutes.

Next, a temperature raising process is carried out in a temperature raising period T20 from the time t11 to a time t20. The temperature raising process is such that the temperature of the semiconductor device 30 is raised from the first temperature to a second temperature, with the chamber in which the semiconductor device 30 is loaded not being exposed to the atmosphere. That is, supplying the indium reducing gas and forming the gate insulating film 43, to be described hereafter, are executed consecutively in the same chamber. N₂ gas, for example, is supplied into the chamber in the temperature raising period T20.

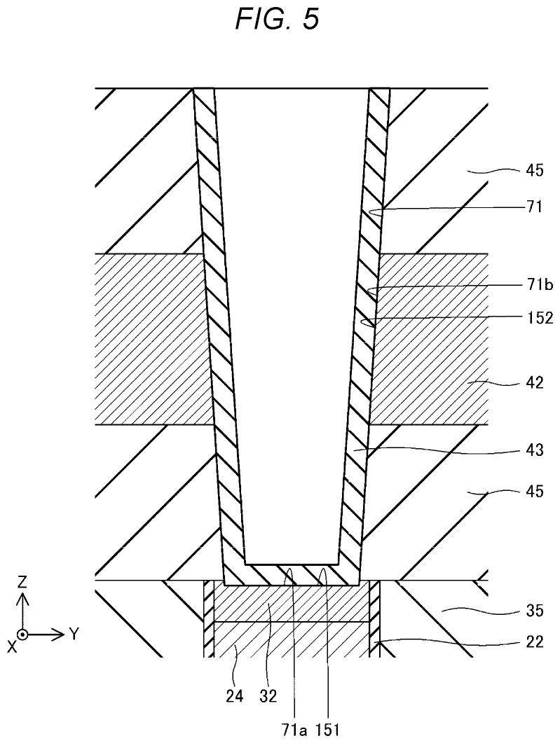

Next, as shown in FIG. 4, a film forming process is carried out in a film forming period T30 from the time t20 to a time t21. The film forming process is carried out by a film forming gas being supplied to the chamber at the second temperature, which is higher than the first temperature. As shown in FIG. 5, the gate insulating film 43 is formed in the hole portion 71 of the semiconductor device 30.

Specifically, the second temperature is 400 degrees Celsius or greater. In the present embodiment, the second temperature is, for example, 450 degrees Celsius.

Forming the gate insulating film 43 includes repeatedly supplying a first gas including silicon for a second time, which is shorter than the length of the first time, and supplying a second gas including nitrogen for a third time, which is shorter than the length of the first time. Herein, the second time is 0.2 times or less as long as the first time. The third time is 0.2 times or less as long as the first time.

The first gas may be a gas of the same kind as the reducing gas used in the soaking period T10. Specifically, the first gas is, for example, HCD. The second gas is, for example, NH₃.

Specifically, during the film forming process, a supply of the first gas, which is a silicon supplying material, and a supply of the second gas, which is a nitriding agent such as NH₃, N₂H₂, N₂H₄, or N₃H₈, are repeated sequentially.

In the present embodiment, during the film forming process in the film forming period T30, an ALD unit process P300 is executed repeatedly. The ALD unit process P300 is repeated in the region of, for example, 100 times.

The ALD unit process P300 includes processes P1, P2, P3, and P4. The processes P1, P2, P3, and P4 are executed in that order.

In the process P1, the first gas is supplied for the second time. Specifically, HCD, which is one example of a first gas, is supplied. The time for which the HCD is supplied is, for example, 5 seconds or more, 30 seconds or less.

In the process P2, the chamber is purged after being evacuated. A time for which the chamber is evacuated is, for example, 5 seconds or more, and within 60 seconds. A purging time is, for example, 5 seconds or more, 60 seconds or less.

In the process P3, the second gas is supplied for the third time. Specifically, NH₃, which is one example of a second gas, is supplied. The time for which the NH₃ is supplied is, for example, 10 seconds or more, 60 seconds or less.

In the process P4, the chamber is purged for the next ALD unit process P300 after being evacuated. A time for which the chamber is evacuated is, for example, 5 seconds or more, and within 60 seconds. A purging time is, for example, 5 seconds or more, 60 seconds or less.

The gate insulating film 43 is formed on the bottom face 71a and the side face 71b of the hole portion 71 in the semiconductor device 30 by the film forming process in the film forming period T30 (refer to FIG. 5).

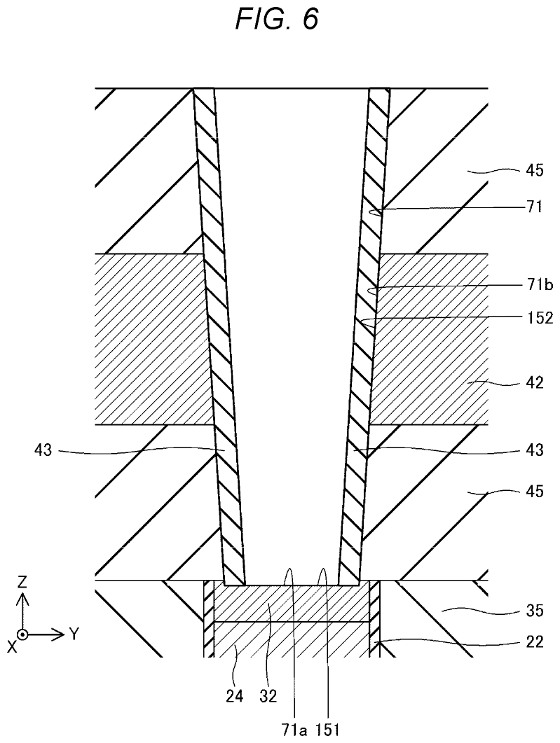

Next, as shown in FIG. 6, the surface 151 of the lower electrode 32 is exposed by the gate insulating film 43 formed above the lower electrode 32 being etched.

Next, after the semiconductor substrate is transferred from the chamber (Load out), the oxide semiconductor layer 70 is deposited in an interior of the hole portion 71, as shown in FIG. 7. Because of this, a channel that is connected to the lower electrode 32, and has a face 70c that opposes the conductive layer 42 across the gate insulating film 43, is formed.

The gate insulating film 43 may be, for example, a silicon oxide film, or a stacked body of a silicon oxide film and a silicon nitride film. The gate insulating film 43 may include a high dielectric material such as alumina (Al₂O₃). When the gate insulating film 43 is a silicon oxide film, a supply of the first gas, which is a silicon supplying material, and a supply of the second gas, which is an oxidizing agent such as O₂, O₃, or H₂O, are repeated sequentially.

### Problem

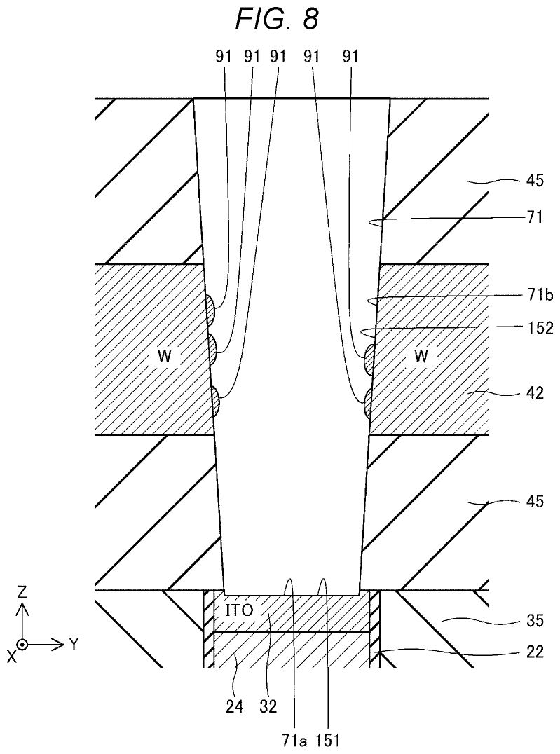

A case in which heat treatment is carried out on the semiconductor device 30 in a state in which ITO is exposed on the surface 151 and tungsten is exposed on the surface 152, as shown in FIG. 8, is envisaged. For example, heat treatment during formation of the gate insulating film 43 is envisaged.

On the surface 151, the temperature rises due to the heating, and the indium in the ITO transitions to a gaseous state. An indium mass 91 may be formed on the surface 152 due to the indium in the gaseous state adhering to the surface 152. The indium mass 91 is, for example, a metal crystal fragment or an aggregate of minute atoms.

Adhering of indium to the surface 152 may also occur when, for example, the hole portion 71 is formed using a reactive ion etching.

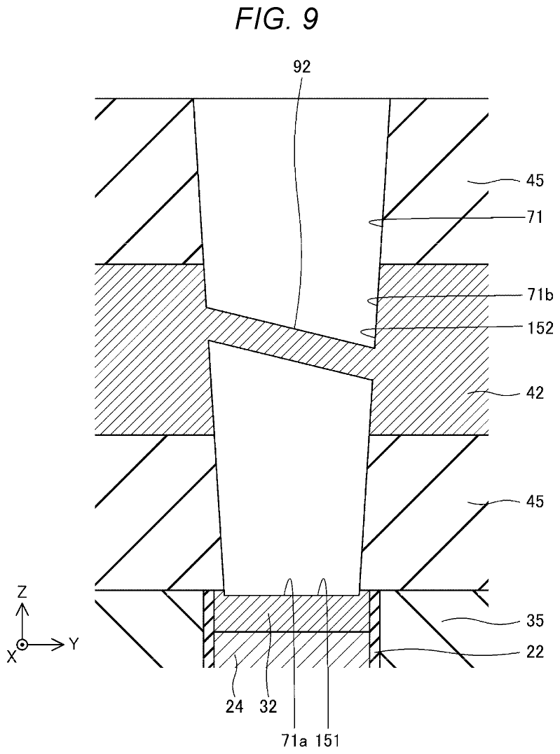

When heat treatment is carried out in a state in which the indium mass 91 is adhering to the surface 152 in which tungsten is exposed, a whisker may be formed on the surface 152, as shown in FIG. 9. The whisker is, for example, a whisker-form tungsten crystal protruding outwardly from the surface 152. Formation of the whisker is liable to occur at, for example, 350 degrees Celsius or greater.

When, provisionally, the film forming process is carried out at 450 degrees Celsius without carrying out the reducing gas supply process in the soaking period T10 (refer to FIG. 4), the possibility of a whisker being formed increases. When the whisker grows, the whisker may block one portion of the hole portion 71 or the entire hole portion 71.

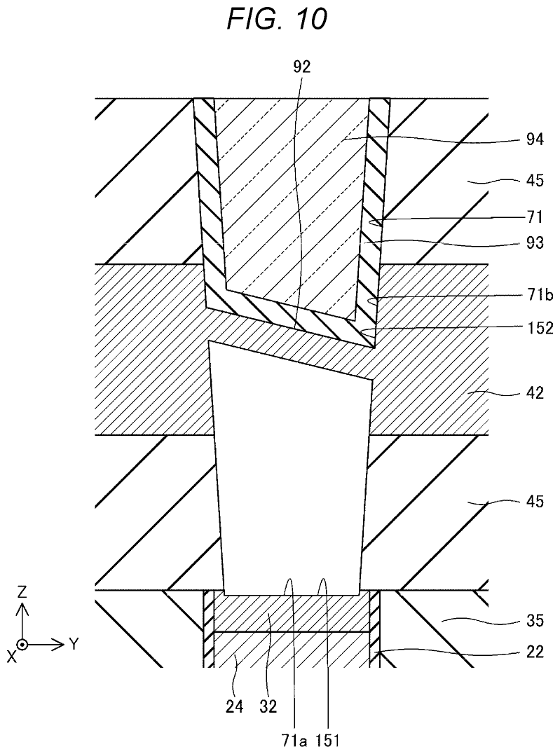

When a formation of a gate insulating film 93 and a formation of an oxide semiconductor layer 94 are carried out in the semiconductor device 30 in which one portion of the hole portion 71 or the entire hole portion 71 is blocked, as shown in FIG. 10, the oxide semiconductor layer 94 does not completely fill the hole portion 71, which is undesirable, as the oxide semiconductor layer 94 does not function well as a channel.

### Advantages

In the present embodiment, the reducing gas supply process is carried out in the soaking period T10, as shown in FIG. 4, because of which the indium mass 91 on the surface 152 (refer to FIG. 8) can be caused to transition to a gaseous state and decrease using the indium reducing gas. Because of this, blocking of one portion of the hole portion 71 or the entire hole portion 71 can be suppressed, meaning that the gate insulating film 43 and the oxide semiconductor layer 70 can be formed well, and the oxide semiconductor layer 70 can be caused to function well as a channel. As a result of this, a semiconductor storage device having excellent transistor properties can be formed.

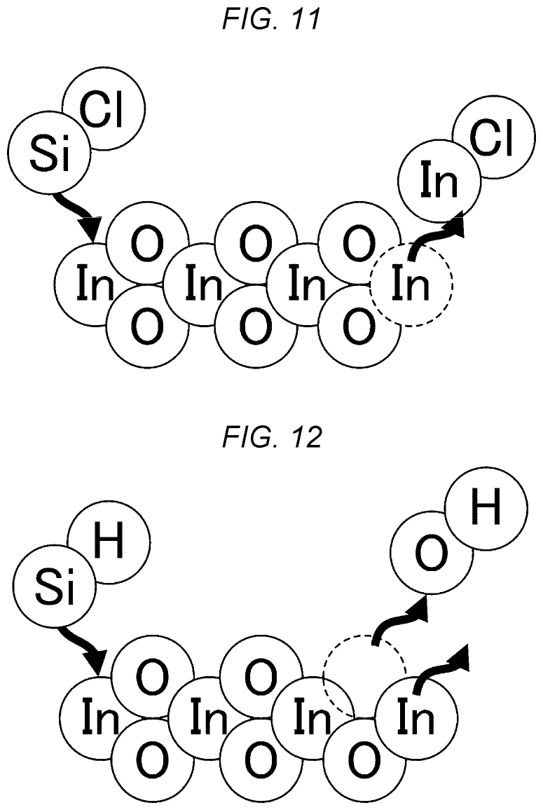

The following reaction occurs in the lower electrode 32 including ITO during the reducing gas supply process and the film forming process. That is, when a gas including an Si—X bond is used as the indium reducing gas, the indium in the ITO of the lower electrode 32 transitions to a gaseous state as an indium halide, as shown in FIG. 11. The gas including the Si—X bond is, for example, a gas of an inorganic material. That gas is, for example, HCD.

When the indium transitions to a gaseous state, the oxygen in the ITO remains in the ITO. Because of this, an increase in oxygen vacancies in the ITO can be suppressed. A movement of oxygen from the oxide semiconductor layer 70 to the lower electrode 32 including ITO is restricted. Because of this, an amount of oxygen vacancies, which are carriers, in the oxide semiconductor layer 70 stabilizes, and by extension, a threshold voltage can be stabilized.

When a gas including an Si—X bond, such as HCD, is used as the indium reducing gas, a halogen may be provided in the lower electrode 32. When halogen atoms, which have high electronegativity, are provided in the lower electrode 32, a movement of the oxygen in the ITO can be suppressed. A movement of the oxygen in the oxide semiconductor layer 70 to the ITO can be suppressed.

Also, the lower electrode 32 includes portions 32a and 32b (refer to FIG. 7). The portion 32a is positioned in an upper portion of an interior of the lower electrode 32, and includes the surface 151. The portion 32b is positioned below the portion 32a, and does not include the surface 151. The lower electrode 32 includes a portion, the portion 32a for example, in which a concentration of halogen atoms is high in comparison with a concentration of halogen atoms in one portion of the metal oxide layer 50a or the entire metal oxide layer 50a. For example, the concentration of halogen atoms in the portion 32a of the lower electrode 32 is high in comparison with that in the portion 32b.

When a gas of an organic material is used as the indium reducing gas, the oxygen in the ITO of the lower electrode 32 easily bonds with hydrogen, whereby the oxygen in the ITO decreases, as shown in FIG. 12. As a result of this, indium that is not bonded with oxygen increases, and as a melting point of indium is low, the indium transitions to a gaseous state more easily.

In this case, the oxygen in the ITO in the lower electrode 32 decreases, and contact resistance between the lower electrode 32 and the oxide semiconductor layer 70 can be reduced, because of which an on-state current Ion of the field-effect transistor 40 can be increased. Also, the oxide semiconductor layer 70 is formed in a tapered form, and an area of contact between the oxide semiconductor layer 70 at the lower end 70b and the lower electrode 32 may be smaller than an area of contact between the oxide semiconductor layer 70 at the upper end 70a and the metal oxide layer 50a. In this case, the contact resistance between the lower electrode 32 and the oxide semiconductor layer 70 is low in comparison with contact resistance between the upper electrode 50 and the oxide semiconductor layer 70, whereby good transistor properties can be obtained. When a gas including both an Si—X bond and a C—H bond, such as DCS, is used as the indium reducing gas, hydrogen in the DCS first reacts with indium, and then the reaction shown in FIG. 12 takes place.

Also, a concentration of silicon in the portion 32a is greater than a concentration of silicon in the portion 32b. This is because silicon adheres to the surface 151 when the gate insulating film 43 is formed.

Also, in the lower electrode 32, a concentration of indium in the portion 32a is smaller than a concentration of indium in the portion 32b. This is because the indium of the surface 151 halogenates and transitions to a gaseous state, or transitions to a gaseous state as it is, because of the aforementioned reaction.

Also, when a gas of an organic material is supplied as the indium reducing gas, a concentration of carbon in the portion 32a becomes greater than a concentration of carbon in the portion 32b. As carbon is of the same family as tin, the carbon in the lower electrode 32 has the same function as tin, which is to increase a conductivity of the ITO. Because of this, conductivity in the portion 32a is high in comparison with conductivity in the portion 32b.

### Second Embodiment

A method of manufacturing the semiconductor device 30 according to a second embodiment will be described. From the second embodiment onward, a description that is common to that of the first embodiment will be omitted, and only different points will be described. In addition, identical operational advantages provided by identical configurations will not be repeated.

When compared with the method of manufacturing the semiconductor device 30 according to the first embodiment shown in FIG. 4, the method of manufacturing the semiconductor device 30 according to the second embodiment differs from the method of manufacturing the semiconductor device 30 according to the first embodiment in that a film formation at low temperature is carried out after the reducing gas supply process in the soaking period T10.

In the method of manufacturing the semiconductor device 30 according to the second embodiment, film formation is carried out on the structure after the indium reducing gas is supplied at a temperature equal to or greater than the first temperature and lower than the second temperature.

Specifically, a low temperature film forming period T16 is provided between the soaking period T10 and the temperature raising period T20. In the present embodiment, a low temperature film forming process in the low temperature film forming period T16 includes the ALD unit process P300 that is executed repeatedly. The ALD unit process P300 repeated in the low temperature film forming process is the same as the ALD unit process P300 shown in FIG. 4.

The low temperature film forming period T16 is shorter than the film forming period T30. The number of times the ALD unit process P300 of the low temperature film forming period T16 is repeated is smaller than the number of times the ALD unit process P300 of the film forming period T30 is repeated. In the low temperature film forming period T16, the ALD unit process P300 is repeated, for example, 10 times, 50 times, or 100 times.

Also, a temperature at which the low temperature film forming process is carried out is, for example, the same as the first temperature of the soaking period T10 at, for example, 300 degrees Celsius. The temperature at which the low temperature film forming process is carried out may be another temperature, provided that the temperature is equal to or greater than the first temperature and lower than the second temperature.

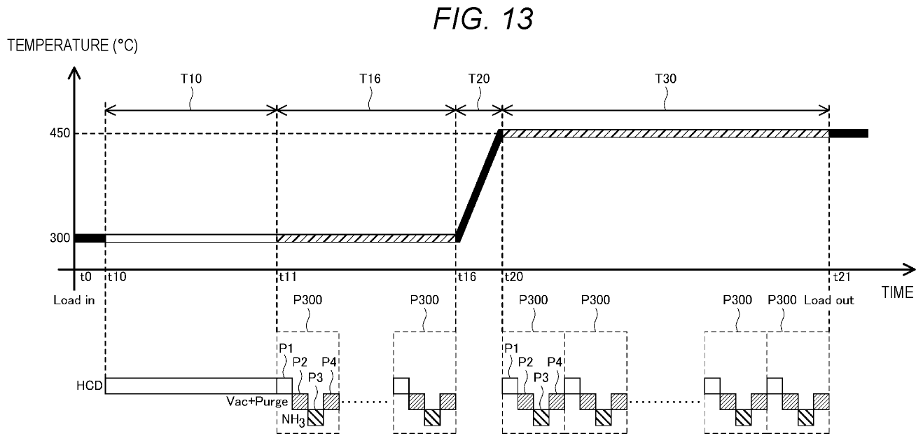

In the method of manufacturing the semiconductor device 30 shown in FIG. 13, because of the low temperature film forming process in the low temperature film forming period T16, the indium mass 91 adhering to the surface 152 can be caused to transition to a gaseous state. In the same way as in the first embodiment, a semiconductor storage device having excellent transistor properties can be formed.

Furthermore, a film is formed on the ITO of the lower electrode 32 by the low temperature film forming process in the low temperature film forming period T16, as a result of which the surface 151 can be protected. Because of this, a separation of indium and oxygen from the ITO of the lower electrode 32 can be suppressed, as with the mechanism shown in, for example, FIG. 12, as a result of which damage such as coarsening caused by heat of the ITO of the lower electrode 32 can be suppressed.

### Third Embodiment

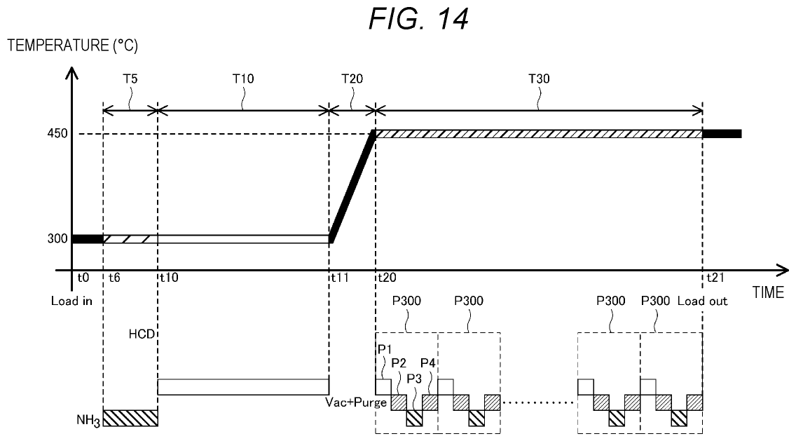

A method of manufacturing the semiconductor device 30 according to a third embodiment will be described. When compared with the method of manufacturing the semiconductor device 30 according to the first embodiment shown in FIG. 4, the method of manufacturing the semiconductor device 30 according to the third embodiment differs in that an annealing process using ammonia is carried out immediately before the reducing gas supply process in the soaking period T10, as shown in FIG. 14.

In the method of manufacturing the semiconductor device 30 according to the third embodiment, a film is formed on at least the surface 151 by a fourth gas that includes nitrogen at a third temperature being supplied to the hole portion 71 including the surface 151, where ITO is exposed, and the surface 152, where tungsten is exposed.

Specifically, an ammonia annealing period T5 is provided immediately before the soaking period T10. In the present embodiment, during an ammonia annealing process in the ammonia annealing period T5, an ammonia gas is supplied into the chamber.

A length of the ammonia annealing period T5 is greater than that of the process P3. The length of the ammonia annealing period T5 is, for example, 10 to 60 minutes. In the present embodiment, an ammonia annealing process is carried out at the third temperature in the ammonia annealing period T5. The third temperature is lower than the second temperature. The third temperature is, for example, the same as the first temperature of the soaking period T10 at, for example, 300 degrees Celsius. The third temperature is preferably 350 degrees Celsius or lower.

Furthermore, in the method of manufacturing the semiconductor device 30 shown in FIG. 14, the surface 151 of the lower electrode 32 can be nitrided by the ammonia annealing process in the ammonia annealing period T5. The gasifying of indium from the ITO of the lower electrode 32 can be suppressed. In the same way as in the first embodiment, a semiconductor storage device having excellent transistor properties can be formed.

Also, the tungsten of the surface 152 of the conductive layer 42 is nitrided by carrying out an annealing process using ammonia in T5. Because of this, whisker formation when the indium mass 91 adheres to the tungsten surface can be suppressed.

### Fourth Embodiment

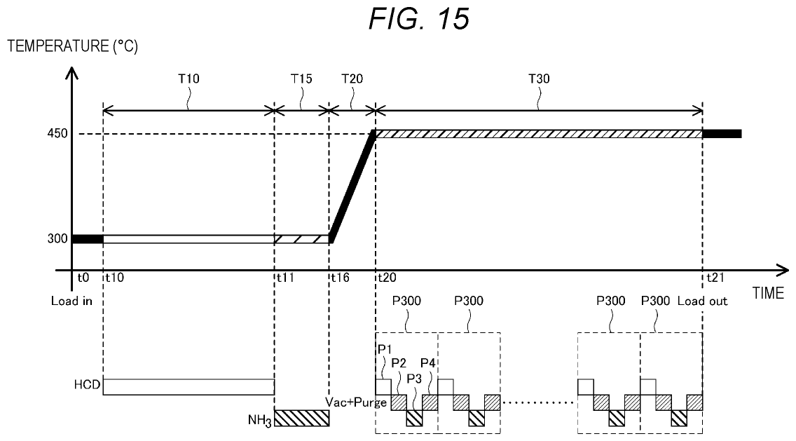

A method of manufacturing the semiconductor device 30 according to a fourth embodiment will be described. When compared with the method of manufacturing the semiconductor device 30 according to the third embodiment shown in FIG. 14, the method of manufacturing the semiconductor device 30 according to the fourth embodiment differs in that an annealing process using ammonia is carried out immediately after the reducing gas supply process in the soaking period T10, as shown in FIG. 15, instead of the ammonia annealing process in the ammonia annealing period T5.

In the method of manufacturing the semiconductor device 30 according to the fourth embodiment, a third gas that includes nitrogen is supplied at a temperature equal to or lower than the first temperature to the hole portion 71 after the indium reducing gas is supplied.

Specifically, an ammonia annealing period T15 is provided between the soaking period T10 and the temperature raising period T20.

In the present embodiment, an ammonia annealing process in the ammonia annealing period T15 is the same as the ammonia annealing process in the ammonia annealing period T5 shown in FIG. 14. Alternatively, ammonia annealing process in the ammonia annealing period T15 may differ from the ammonia annealing process in the ammonia annealing period T5 shown in FIG. 14.

A length of the ammonia annealing period T15 is greater than that of the process P3. The length of the ammonia annealing period T15 is, for example, 10 to 60 minutes. An ammonia annealing process is carried out at a fourth temperature in the ammonia annealing period T15. The fourth temperature is, for example, the same as the first temperature of the soaking period T10 at, for example, 300 degrees Celsius. In the same way as in the first embodiment, a semiconductor storage device having excellent transistor properties can be formed.

Furthermore, in the method of manufacturing the semiconductor device 30 shown in FIG. 15, the surface 151 of the lower electrode 32 can be nitrided by the ammonia annealing process in the ammonia annealing period T15.

Also, the tungsten of the surface 152 of the conductive layer 42 is nitrided by carrying out an annealing process using ammonia in T15. By the tungsten being nitrided, whisker formation when the indium mass 91 adheres to the tungsten surface can be suppressed.

Also, for example, when the reducing gas supply process in the soaking period T10 is sufficiently carried out, a film of one layer or more is formed on the tungsten in the surface 152 of the conductive layer 42 by the reducing gas supply process. Further, the film on the tungsten is nitrided by carrying out an annealing process using ammonia in the ammonia annealing period T15. Because of this, exposure of the tungsten in the surface 152 of the conductive layer 42 can be suppressed, as of result of which the surface 152 can be protected from whisker formation.

### Fifth Embodiment

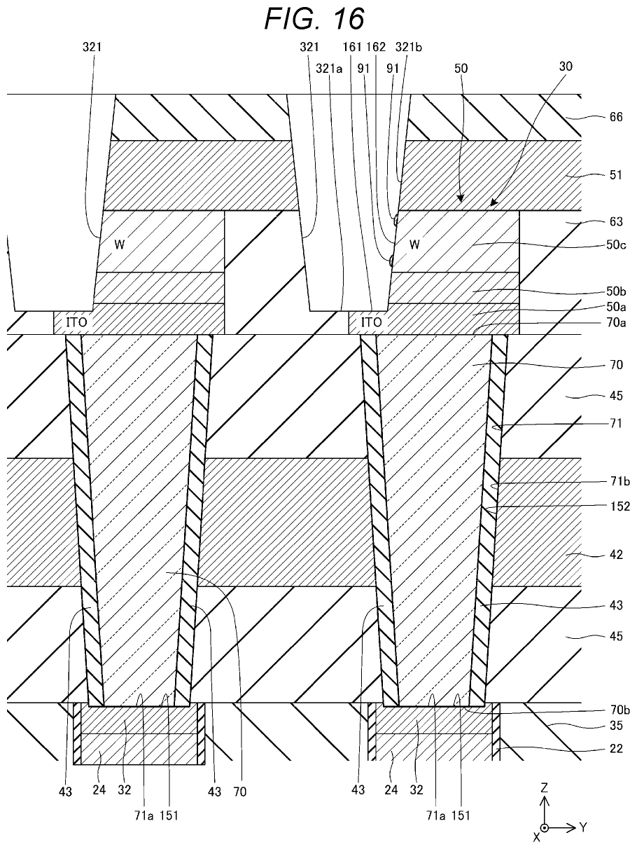

A method of manufacturing the semiconductor device 30 according to a fifth embodiment will be described. In the first embodiment, a manufacturing method in which an indium reducing gas is supplied to the hole portion 71, which is a transistor hole, is described, but in the fifth embodiment, a manufacturing method in which an indium reducing gas is supplied to a groove portion provided between bit lines, as shown in FIG. 16, will be described.

In the semiconductor device 30 according to the fifth embodiment, a bit line (BL)-landing pad (LP) groove portion 321 is formed between two neighboring conductive layers 51. A conductor is embedded in the BL-LP groove portion 321 in a subsequent process.

The BL-LP groove portion 321 is formed by etching. The BL-LP groove portion 321 has a bottom face 321a in a lower portion and an upper portion that is opened, and the BL-LP groove portion 321 extends along the X axis direction.

The bottom face 321a in the lower portion of the BL-LP groove portion 321 includes a surface 161 in which ITO is exposed. Specifically, the surface 161 is one portion of the metal oxide layer 50a of the upper electrode 50 exposed when the BL-LP groove portion 321 is formed.

A side face 321b in the Y axis+direction of the BL-LP groove portion 321 includes a surface 162 in which tungsten is exposed. Specifically, the surface 162 is one portion of the metal film 50c, which is a landing pad, exposed when the BL-LP groove portion 321 is formed.

In a state in which ITO is exposed in the surface 161 and tungsten is exposed in the surface 162 in this way, for example, a film may be formed above an insulating layer 66 in the semiconductor device 30.

Because of heat treatment when forming a film, the indium in the ITO at the surface 161 transitions to a gaseous state, and the indium mass 91 may be formed on the surface 162 by the indium in the gaseous state adhering to the surface 162.

Adhering of indium to the surface 162 may also occur when, for example, the BL-LP groove portion 321 is formed using a reactive ion etching.

In these cases, the indium mass 91 on the surface 162 can be caused to transition to a gaseous state and decrease by applying the manufacturing processes shown in FIGS. 4, 13, 14, and 15. Because of this, a formation of a whisker on the surface 162 including tungsten can be suppressed.

In the embodiments, a configuration in which tungsten is exposed in the surfaces 152 and 162 is described, but this is not a limiting example. Another configuration may include another metal that is exposed in the surfaces 152 and 162.

Also, in the embodiments, a configuration in which ITO is exposed in the surfaces 151 and 161 is described, but this is not a limiting example. Another configuration may include indium that is exposed in the surfaces 151 and 161. Objects of the present disclosure can also be achieved with this configuration.

A semiconductor device according to an embodiment includes an insulating layer, an oxide semiconductor that is formed in the insulating layer, extends in a first direction, and has a first end and a second end, a first conductive film that comes into contact with the first end of the oxide semiconductor and is formed of a metal oxide, a second conductive film that comes into contact with the second end of the oxide semiconductor and is formed of the metal oxide, and a gate electrode that is opposed across an insulating film between the first end and the second end of the oxide semiconductor and is formed of a metal. In this semiconductor device, the second conductive film includes a portion in which a concentration of halogen atoms is high in comparison with a concentration of the halogen atoms in one portion of the first conductive film or the entire first conductive film.

A semiconductor device according to another embodiment includes an insulating layer, an oxide semiconductor that is formed in the insulating layer, extends in a first direction, and has a first end and a second end, a first conductive film that comes into contact with the first end of the oxide semiconductor and is formed of a metal oxide, a second conductive film that comes into contact with the second end of the oxide semiconductor and is formed of the metal oxide, and a gate electrode that is opposed across an insulating film between the first end and the second end of the oxide semiconductor. In this semiconductor device, a conductivity of the second conductive film is greater than a conductivity of the first conductive film.

A semiconductor storage device according to an embodiment includes the semiconductor device, a first capacitor electrode connected to the first conductive film and the second conductive film, a second capacitor electrode that opposes the first capacitor electrode, and a dielectric film provided between the first capacitor electrode and the second capacitor electrode.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device manufacturing method, comprising:
transferring a substrate including a structure that has a first surface at which indium is exposed, and a second surface at which a first metal is exposed, to a chamber of a film forming device;
supplying an indium reducing gas to the chamber at a first temperature at which indium is able to transition to a gaseous state; and
supplying a film forming gas to the chamber at a second temperature higher than the first temperature to form a first film on the first surface and the second surface, after supplying the reducing gas.

2. The semiconductor device manufacturing method according to claim 1, wherein the first metal includes tungsten.

3. The semiconductor device manufacturing method according to claim 1, wherein the film forming gas is supplied without exposing the chamber to the atmosphere after supplying the reducing gas.

4. The semiconductor device manufacturing method according to claim 1, wherein the film forming gas includes the reducing gas.

5. The semiconductor device manufacturing method according to claim 4, wherein the second temperature is 400 degrees Celsius or greater.

6. The semiconductor device manufacturing method according to claim 1, wherein said supplying of the film forming gas includes repeatedly supplying a first gas that includes silicon and a second gas that includes nitrogen.

7. The semiconductor device manufacturing method according to claim 6, wherein
the reducing gas is supplied for a first time period, and
each time the first gas is supplied, the first gas is supplied for a second time period shorter than the first time period, and each time the second gas is supplied, the second gas is supplied for a third time period shorter than the first time period.

8. The semiconductor device manufacturing method according to claim 7, wherein the second time period is 0.2 times the first time period or less.

9. The semiconductor device manufacturing method according to claim 7, wherein the first gas and the reducing gas are the same kind of gas.

10. The semiconductor device manufacturing method according to claim 1, further comprising:
supplying the film forming gas at a temperature lower than the second temperature after supplying the reducing gas and before supplying the film forming gas at the second temperature.

11. The semiconductor device manufacturing method according to claim 1, further comprising:
supplying a fourth gas that includes nitrogen at a third temperature lower than the second temperature before supplying the reducing gas.

12. The semiconductor device manufacturing method according to claim 1, further comprising:
supplying a third gas that includes nitrogen at a fourth temperature equal to or lower than the first temperature after supplying the reducing gas and before supplying the film forming gas at the second temperature.

13. The semiconductor device manufacturing method according to claim 12, further comprising:
transferring the substrate out from the chamber after supplying the film forming gas; and
forming an oxide semiconductor on the substrate transferred out from the chamber, wherein
the oxide semiconductor is connected to the first surface, and opposes the second surface across the first film.

14. The semiconductor device manufacturing method according to claim 11, wherein the third temperature is 350 degrees Celsius or lower.

15. The semiconductor device manufacturing method according to claim 1, further comprising:
forming the structure having a bottom face that includes the first surface at which indium is exposed and a side face that includes the second surface at which the first metal is exposed, by etching, before supplying the reducing gas.

16. A semiconductor device manufacturing method, comprising:
forming a hole in a structure that is on a substrate to expose indium a bottom surface of the hole and a metal on a side surface of the hole;
transferring the substrate having the structure with the hole into a chamber;
supplying an indium reducing gas to the chamber at a first temperature at which indium is able to transition to a gaseous state;
after supplying the reducing gas, supplying a film forming gas to the chamber at a second temperature higher than the first temperature to form a film on the bottom surface and the side surface;
removing the film formed on the bottom surface; and
depositing an oxide semiconductor layer into the hole.

17. The semiconductor device manufacturing method according to claim 16, wherein said supplying of the film forming gas includes repeatedly supplying a first gas that includes silicon and a second gas that includes nitrogen.

18. The semiconductor device manufacturing method according to claim 16, further comprising:
supplying the film forming gas at a temperature lower than the second temperature after supplying the reducing gas and before supplying the film forming gas at the second temperature.

19. The semiconductor device manufacturing method according to claim 16, further comprising:
supplying a fourth gas that includes nitrogen at a third temperature lower than the second temperature before supplying the reducing gas.

20. The semiconductor device manufacturing method according to claim 16, further comprising:
supplying a third gas that includes nitrogen at a fourth temperature equal to or lower than the first temperature after supplying the reducing gas and before supplying the film forming gas at the second temperature.
